(19) United States
(12) Patent Application Publication
(10) Pub. No.: US 2023/0170356 A1
(43) Pub. Date: Jun. 1, 2023

(54) ARRAY SUBSTRATE AND DISPLAY DEVICE

(71) Applicants: MIANYANG HKC OPTOELECTRONICS TECHNOLOGY CO., LTD., Mianyang (CN); HKC CORPORATION LIMITED, Mianyang (CN)

(72) Inventors: ZHIWEI LI, Mianyang (CN); Haoxuan ZHENG, Mianyang (CN)

(21) Appl. No.: 17/993,888

(22) Filed: Nov. 24, 2022

(30) Foreign Application Priority Data
Nov. 30, 2021 (CN) 202111445585.4

(51) Int. Cl. H01L 27/12; H05K 1/18

(52) U.S. Cl. CPC H01L 27/1244; H05K 1/189; H05K 2201/10136

(57) ABSTRACT

An array substrate and a display device are disclosed. The array substrate includes a display region and a non-display region, and further includes a base substrate, multiple extension wires, a bonding member, and a flexible circuit board. The extension wires are arranged on a front side of the base substrate and in the non-display region. The bonding member includes a plurality of bonding pins, which are disposed in the non-display region. The flexible circuit board is arranged on a back side of the base substrate. Multiple first through holes are defined in the flexible circuit board. A first conductive layer is disposed in each first through hole. One end of each extension wire adjacent to the respective first through hole is electrically connected to one end of the flexible circuit board through the first conductive layer. The other end of the flexible circuit board is connected to the bonding pins.

### CROSS-REFERENCE TO RELATED APPLICATIONS

This application claims the priority and benefit of Chinese patent application 2021114455854, entitled “Array Substrate and Display Device” and filed Nov. 30, 2021, with China National Intellectual Property Administration, the entire contents of which are incorporated herein by reference.

### TECHNICAL FIELD

The present application relates to the field of display technology, and in particular, to an array substrate and a display device.

### BACKGROUND

With the development of display technology, flat-panel displays are currently the mainstream displays. Among them, liquid crystal displays are widely used in electronic products such as computer screens, flat-screen TVs, and mobile phones because of their advantages of thin appearance and power saving. A liquid crystal display includes a liquid crystal display panel, a backlight module, a driving circuit board, and so on. A liquid crystal display panel generally includes an array substrate and a counter substrate. The array substrate includes data lines, scan lines, etc. corresponding to the display region, and extension wires and fan-out traces, etc. corresponding to the non-display region, where the extension wires connect the fan-out traces with the data lines or scan lines.

The layout of fan-out traces in related designs is fan-shaped. Due to the wiring method, the length of each fan-out trace is different, and the resistance is also different. In order to balance the resistance of each fan-out trace, the wire resistance of each fan-out trace is made the same by winding each fan-out trace. However, the wiring method requires a certain wiring space, so that the fan-out wiring occupies more wiring space corresponding to the non-display region of the display panel, which is not suitable for the current narrow-bezel display panels. Therefore, how to design the fan-out wiring becomes an urgent problem to be solved by those skilled in the art.

### SUMMARY

In view of the above, it is a purpose of the present application to provide an array substrate and a display device, which saves the wiring space for fan-out wiring and realizes a display panel with a narrower bezel.

The present application discloses an array substrate including a display region and a non-display region. The array substrate further includes a base substrate, a plurality of extension wires, a bonding member, and a flexible circuit board. The plurality of extension wires are arranged on a front side of the base substrate and are located in the non-display region. The bonding member includes a plurality of bonding pins, and the plurality of bonding pins are arranged in the non-display region. The flexible circuit board is arranged on the back side of the base substrate. The base substrate is provided with a plurality of first through holes. A first conductive layer is disposed in the first through hole. One end of the extension wire adjacent to the first through hole is electrically connected to one end of the flexible circuit board through the first conductive layer. The other end of the flexible circuit board is connected to the bonding pins of the bonding member.

Optionally, the bonding pins are arranged on the front side of the base substrate. The base substrate is further provided with a plurality of second through holes. A second conductive layer is disposed in the second through hole. The other end of the flexible circuit board is electrically connected to the bonding pins through the second conductive layer in the second through hole.

Optionally, the bonding member includes a first bonding portion and a second bonding portion. The first bonding portion includes a plurality of first bonding pins. The second bonding portion includes a plurality of second bonding pins. Taking one of the extension wires in the middle as the center line, along the wire length direction of the extension wires, the plurality of extension wires gradually converge toward the center line, and the distance between two adjacent extension wires near the end of the first through holes is smaller than the distance between two adjacent extension wires near the end of the display region. The first bonding portion and the second bonding portion are respectively arranged on both sides of the extension wires. The flexible circuit board includes a first flexible circuit board and a second flexible circuit board. The plurality of extension wires includes a plurality of first extension wires and a plurality of second extension wires. The first extension wires are connected to the first bonding pins through the first flexible circuit board. The second extension wires are connected to the second bonding pins through the second flexible circuit board.

Optionally, the bonding pins are arranged on the back side of the base substrate.

Optionally, the orthographic projection of the region where the bonding pins are located on the base substrate overlap the orthographic projection of the region where the extension wires are located on the base substrate.

Optionally, the distance between the bonding member and the extension wires is smaller than the length of the flexible circuit board.

Optionally, a plurality of signal traces are provided on the flexible circuit board, and the wire resistances of the plurality of signal traces are equal.

Optionally, in the wire width direction of the extension wires, two adjacent first through holes are staggered.

The present application further discloses a display device, including a display panel and a backlight module. The display panel includes a counter substrate and the above-mentioned array substrate. The backlight module includes a back plate. The back plate is disposed on the side of the array substrate away from the counter substrate. The back plate is provided with a groove corresponding to the flexible circuit board. The flexible circuit board is accommodated in the groove.

Optionally, the display device further includes a driving circuit board, and the driving circuit board is bonded with the bonding pins.

In the present application, a first through hole is provided in the base substrate, and the first conductive layer in the first through hole can transmit the signal on the extension wire on the front side of the base substrate to the back side of the base substrate. Furthermore, a flexible circuit board is arranged on the back side of the base substrate, and the flexible circuit board is connected with the first conductive layer, that is, the signal is transmitted to the flexible circuit board, and the flexible circuit board is connected with the bonding pins. By removing the fan-out traces on the array substrate, a flexible circuit board is used to replace the fan-out traces on the array substrate. The flexible circuit board has the characteristic of being bendable, and so can be appropriately bent and folded on the back of the base substrate. After removing the fan-out traces on the front side of the base substrate, the front side of the base substrate can reduce the space for fan-out traces, thereby reducing the size of the non-display region of the array substrate, and so a narrow-bezel display panel can be realized.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principle of the present application in conjunction with the text description. Apparently, the drawings in the following description merely represent some embodiments of the present disclosure, and for those having ordinary skill in the art, other drawings may also be obtained based on these drawings without investing creative efforts. A brief description of the accompanying drawings is provided as follows.

FIG. 1 is a schematic top view of an array substrate according to a first embodiment of the present application.

FIG. 2 is a schematic cross-sectional view of an array substrate according to the first embodiment of the present application.

FIG. 3 is a schematic diagram of a flexible circuit board according to the first embodiment of the present application.

FIG. 4 is a schematic diagram of a second array substrate according to the first embodiment of the present application.

FIG. 5 is a schematic diagram of a third array substrate according to the first embodiment of the present application.

FIG. 6 is a schematic diagram of a fourth array substrate according to the first embodiment of the present application.

FIG. 7 is a schematic diagram of an array substrate according to the second embodiment of the present application.

FIG. 8 is a schematic diagram of an array substrate according to the third embodiment of the present application.

### DETAILED DESCRIPTION OF EMBODIMENTS

It should be understood that the terms used herein, the specific structures and function details disclosed herein are intended for the mere purposes of describing specific embodiments and are representative. However, this application may be implemented in many alternative forms and should not be construed as being limited to the embodiments set forth herein. As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “front side”, “back side”, “up”, “down”, “left”, “right”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure.

Hereinafter this application will be described in further detail with reference to the accompanying drawings and some optional embodiments.

### Embodiment 1

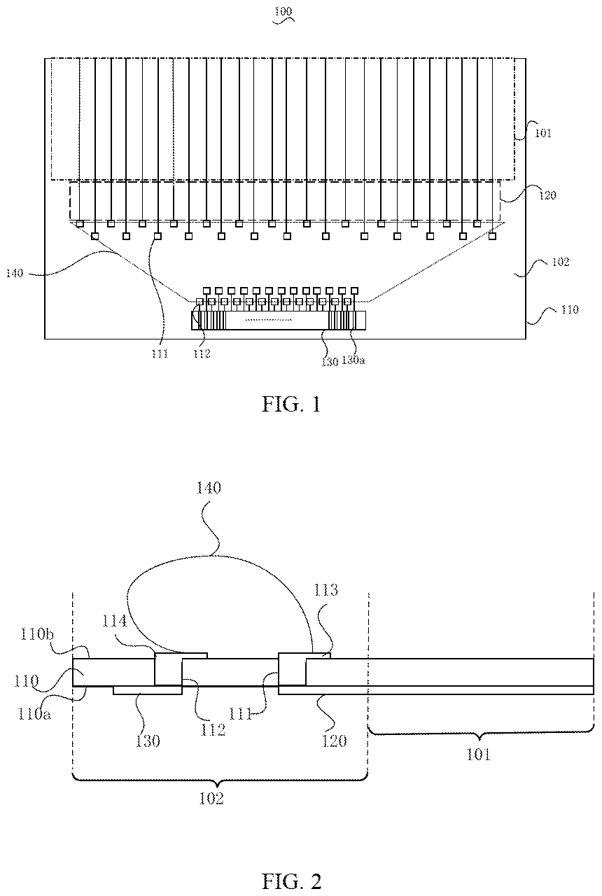

As shown in FIG. 1, as a first embodiment of the present application, a schematic top view of an array substrate is disclosed. The array substrate 100 includes a display region 101 and a non-display region 102. The array substrate 100 further includes a base substrate 110, a plurality of extension wires 120, a bonding member 130 and a flexible circuit board 140. Referring to FIG. 2, the plurality of extension wires 120 are disposed on a front side 110a of the base substrate 110 and located in the non-display region 102. The bonding member 130 includes a plurality of bonding pins 130a, and the plurality of bonding pins 130a are arranged in the non-display region 102. The base substrate 110 is provided with a plurality of first through holes 111, and the first through holes 111 are each disposed at one end of the respective extension wire 120. A first conductive layer 113 is disposed in the first through hole 111. The flexible circuit board 140 is disposed on a back side 110b of the base substrate 110. The extension wires 120 are electrically connected to one end of the flexible circuit board 140 through the respective first conductive layers 113. The other end of the flexible circuit board 140 is connected to the bonding pins 130a.

In the present application, a through hole is provided in the base substrate 110, and the first conductive layer 113 in the through hole can transmit a signal on the extension wire 120 of the front side 110a of the base substrate 110 to the back side 110b of the base substrate 110, and further a flexible circuit board 140 is disposed on the back side 110b of the base substrate 110, and the flexible circuit board 140 is connected to the first conductive layer 113, that is, the signal is transmitted to the flexible circuit board 140, and the flexible circuit board 140 is then connected to the bonding pins 130a. That is, the fan-out traces on the array substrate 100 are removed, and the fan-out traces on the array substrate 100 are replaced by the flexible circuit board 140. Furthermore, the flexible circuit board 140 has the characteristic of being bendable, and can be appropriately bent, and so can be folded on the back side 110 b of the base substrate 110. After removing the fan-out traces on the front side 110a of the base substrate 110, the front side 110a of the base substrate 110 can reduce the space for fan-out traces, thereby reducing the size of the non-display region 102 of the array substrate 100, and so a narrow-bezel display panel can be realized.

It should be noted that the flexible circuit board 140 described here may be FPC (Flexible Printed Circuit), and may also be COF (Chip On Film). However, the flexible circuit board 140 here is different from the driving circuit board in the display panel. Both ends of the flexible circuit board 140 are bonded on the base substrate 110 and the flexible circuit board 140 only functions as connecting wires. The reason why the flexible circuit board 140 needs to be bonded on the back side 110b is because the flexible circuit board 140 on the front side 110a will affect the assembly and display effect of the display panel. Furthermore, this region needs to be coated with sealant, and the flexible circuit board 140 will have a greater impact on the front side 110a. Here, the region where the bonding member 130 is located is the bonding region.

The bonding pins 130a in the present application may be disposed on the front side 110a of the base substrate 110 or the back side 110b of the base substrate 110. For this embodiment, it is taken as an example that the bonding pins 130a are disposed on the front side 110a of the base substrate 110. For arranging the bonding pins 130a on the front side 110a, the signal of the flexible circuit board 140 needs to be retransmitted to the front side 110a of the base substrate 110, so the second through hole 112 also needs to be defined. Specifically, the base substrate 110 is further provided with a plurality of second through holes 112. A second conductive layer 114 is disposed in the second through hole 112. The other end of the flexible circuit board 140 is electrically connected to the bonding pins 130a through the second conductive layers 114 in the second through holes 112. It should be noted that the extension wires 120 are generally connected to data lines or scan lines. The data lines are arranged in the display region 101, the extension wires 120 are arranged in the non-display region 102, and the region where the bonding pins 130a are located may be called a bonding region. In this solution, one end of the extension wire 120 of the non-display region 102 and one end of the bonding pin 130a are respectively provided with a first through hole 111 and a second through hole 112. That is, through holes are formed both in the extension wire 120 and in the bonding region of the non-display region 102, and the flexible circuit board 140 is used for connection therebetween on the back side 110b, which can reduce most of the space required for fan-out wiring. At the same time, since the binding is performed on the front side 110a, the signal test such as GOA (Gate Driver on Array) in the array substrate 100 and the liquid crystal cell test will not be affected, so that the non-display region 102 of the front side 110a of the base substrate 110 of the array substrate 100 is greatly reduced in space, so as to realize a display panel with an ultra-narrow bezel.

As shown in FIG. 2, the first through hole is formed in the base substrate 110 and penetrates through the front side 110a and the back side 110 b of the base substrate 110. The base substrate 110 in the array substrate 100 is generally glass, and the material is silicon dioxide, and hydrogen fluoride can be used to corrode the silicon dioxide to produce silicon tetrafluoride and water. When the base substrate 110 is etched, HF and O2 can be used to etch the base substrate 110, and C4F8 is used as a protective gas, and the cyclic etching method is used to etch in multiple times, so that deep holes can be formed while avoiding bottom defects. The first conductive layer 113 is formed by injecting a silver paste into the through hole. For the through hole injected with silver paste, the exposed silver paste can be set in the shape of the bonding pin 130a, and the general shape of the through hole can also be in the shape of a bonding pin 130a as required. The flexible circuit board 140 can be bonded with the silver paste of the through holes.

In a specific embodiment, the through holes in the base substrate 110 are designed to be disposed in a row, and so the base substrate 110 has a risk of fracture. Therefore, in the wire width direction of the extension wire 120, the two adjacent first through holes 111 can be staggered. The staggered arrangement can refer to arrangement in two rows or three rows or above, etc. Taking two rows as an example, the staggered arrangement is that the through holes are ordered from left to right, the odd through holes are arranged in a row, and the even through holes are arranged in another row. In this arrangement, the through holes are staggered to prevent the number of through holes on one same line of the base substrate 110 from being too large, which may cause the problem of cracking, and thus can mainly avoid the risk of breakage of the base substrate. Of course, the second through hole 112 can also adopt the design of the first through hole 111. Since the width of the region where the bonding member 130 is located is smaller, the multiple bonding pins 130a are denser. Therefore, if the second through holes 112 is arranged in one row, the risk of breakage is relatively high. Therefore, the second through holes 112 may be arranged in multiple rows.

Specifically, the distance between the bonding member 130 and the extension wire 120 is smaller than the length of the flexible circuit board 140. Since the flexible circuit board 140 has certain bending characteristics and is disposed on the back side 110b of the base substrate 110, when forming a display device, a space for accommodating the flexible circuit board 140 may be provided on the back plate. Compared with the fan-out traces in the exemplary technology, the fan-out traces are a condensed trace region that needs to be formed by exposure and development, thereby occupying a large part of the non-display region 102 of the base substrate 110, and it is difficult to achieve further compression due to factors such as machine bottleneck and resistance. By replacing the fan-out traces with the flexible circuit board 140, the signal traces 143 on the flexible circuit board 140 can be further compressed. Compared with the distance between the bonding member 130 and the extension wires 120 in the exemplary technology, this embodiment can compress the distance between the bonding member 130 and the extension wires 120 to a smaller extent. The minimum distance between the extension wires 120 and the bonding member 130 can be just a gap therebetween.

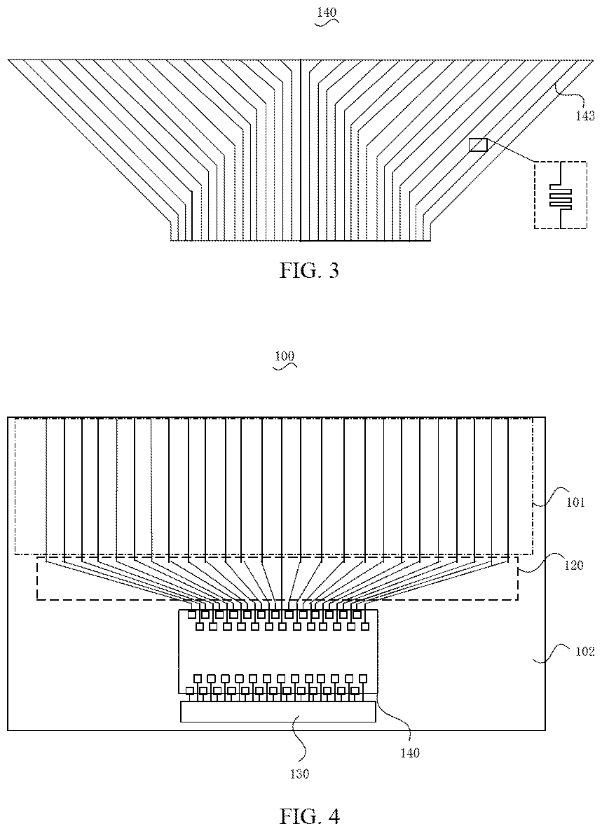

As shown in FIG. 3, a schematic diagram of a flexible circuit board 140 is disclosed. The flexible circuit board 140 is provided with a plurality of signal wires 143, and the wire resistances of the plurality of signal wires 143 are equal. Due to the arrangement of the extension wires 120, the width of the region where the extension wires 120 are located is larger than the width of the region where the bonding member 130 is located. Therefore, one end of the flexible circuit board 140 adjacent to the extension wires 120 is set wider, and the other end is set narrower. Of course, the widths of both ends of the flexible circuit board 140 match the width of the region where the extension wires 120 are located and the width of the region where the bonding member 130 is located, respectively. Therefore, the shape of the front side 110a of the flexible circuit board 140 can be an isosceles trapezoid. Correspondingly, the design of the traces on the flexible circuit board 140 may reference the design of the fan-out traces, that is, according to the arrangement of the fan-out traces provided on the base substrate 110 in the exemplary technology, thus balancing the resistance of each fan-out trace. The resistance of each trace on the flexible circuit board 140 is designed to be equal.

As shown in FIG. 4, a schematic diagram of a second type of array substrate 100 is disclosed as a modified embodiment of the present implementation. Since the spacing between adjacent extension wires 120 is relatively wide, the extension wires 120 can also be condensed. That is, with one of the extension wires 120 in the middle as the center line, along the wire length direction of the extension wires 120, the plurality of extension wires 120 gradually converge toward the center line, and the distance between two adjacent extension wires 120 near the end of the first through hole 111 is smaller than the distance between two adjacent extension wires 120 near the end of the display region 101. The first bonding portion and the second bonding portion are respectively arranged on both sides of the extension wires. The extension wires 120 are gradually converged to a width corresponding to the region where the bonding member 130 is located, and the shape of the front side 110a of the corresponding flexible circuit board 140 can be designed as a rectangle. The extension wires 120 are substantially different from the fan-out traces in the exemplary technology. In particular, the fan-out wiring needs winding, while the extension wires 120 can be straight wires. Therefore, the condense of the extension wires 120 does not need to occupy as much space as the fan-out wiring, and the condensing range of the extension wires 120 can be appropriately compressed. It should be noted that this extension can also be omitted. However, the actual non-display region 102 of the base substrate 110 is not only intended for setting the extension wires 120, but also for setting the testing wiring and the like. The test of the liquid crystal cell, the wiring of the array substrate 100, or the boot-up test all need to be designed in the non-display region 102 of the base substrate, so the extension wires 120 with an appropriate length will not occupy much of the non-display region 102.

Further, the extension wires 120 can also be directly connected to the bonding pins 130a. The extension wires 120 are set as a straight wire without winding, and the difference in resistances of the extension wires 120 caused by the convergence is balanced by the design of the flexible circuit board 140 on the back side 110b. In this way, the area occupied by the non-display region 102 of the base substrate 110 for arranging the fan-out traces can also be saved. It should be noted that the bonding pins 130a are directly connected to the extension wires 120, that is, the flexible circuit board 140 is equivalent to being connected in parallel with the extension wires 120, which on one hand can balance resistance, and on the other and can reduce wire resistance. By changing the resistances of the signal traces 143 on the flexible circuit board 140, the difference in resistances of the extension wires 120 caused by the convergence can be balanced. In addition, because there is the flexible circuit board 140 on the back side 110b that balances the resistances, the converging inclination of the extension wires 120 can be higher. That is, in the length direction of the extension wires 120, the length that can be condensed by the extension wires 120 is even shorter, thereby realizing a narrow-bezel display panel.

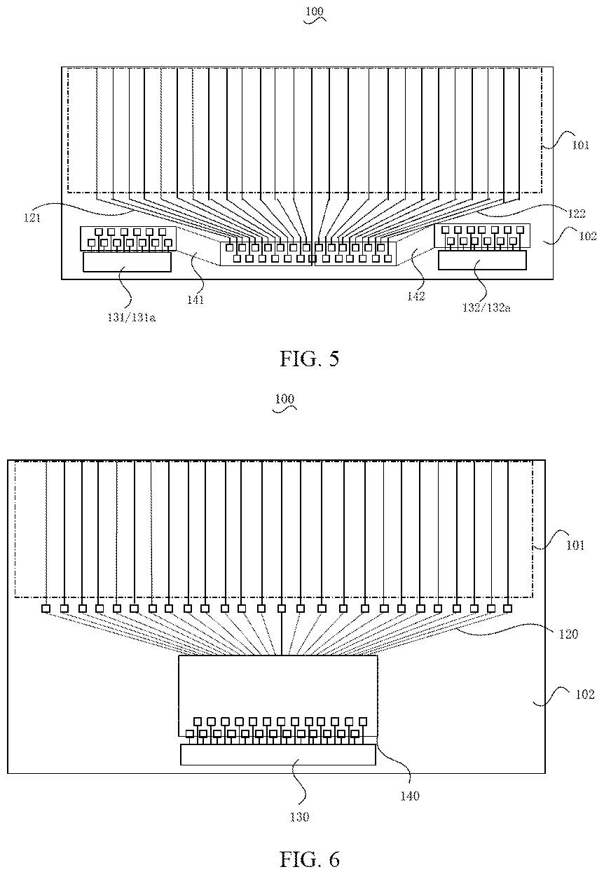

As shown in FIG. 5, as a second implementation of the first embodiment, a schematic diagram of a third array substrate 100 of the first embodiment is disclosed. On the basis of the above-mentioned extension wires 120 that are converged, in this embodiment, the bonding member 130 can also be divided into two parts. Specifically, the bonding member 130 includes a first bonding portion 131 and a second bonding portion 132. The first bonding portion 131 includes a plurality of first bonding pins 131a. The second bonding portion 132 includes a plurality of second bonding pins 132a. Both the first bonding pins and the second bonding pins belong to the bonding pins, and here they are termed the first and the second according to their positions, and are actually substantially the same as the bonding pins in the above-mentioned embodiments. The first bonding pins 131a are arranged on one side of the extension wires 120, and the second bonding pins 132a are arranged on the other side of the extension wires 120. The flexible circuit board 140 includes a first flexible circuit board 141 and a second flexible circuit board 142. The plurality of extension wires 120 include a plurality of first extension wires 121 and a plurality of second extension wires 122. The first extension wires 121 are connected to the first bonding pins 130a through the first flexible circuit board 141. The second extension wires 122 are connected to the second bonding pins 130a through the second flexible circuit board 142. In this embodiment, after the extension wires 120 are condensed, blank areas are left on both sides of the extension wires 120, so that it is equivalent to arranging the first bonding pins 130a and the second bonding pins 130a in the respective blank areas left after the extension wires 120 are converged, thereby further compressing the area occupied by the bonding pins 130a and further reducing the width of the non-display region 102 on the array substrate 100. Of course, the flexible circuit board 140 may also be divided into two, which are respectively connected to the corresponding extension wires 120 and the bonding pins 130a.

As shown in FIG. 6, as another variant of the first embodiment, a schematic diagram of the back side 110b of the third substrate 110 is disclosed. The front side 110a of the base substrate 110 is no longer provided with the extension wires 120, and the extension wires 120 are also provided on the back side 110b of the base substrate 110. The bonding member 130 is arranged in the area vacated on the front side 110a of the base substrate 110. The first through hole 111 is disposed at the end of the extension wires 120 adjacent to the display region 101, and the second through hole 112 is disposed at the end of the bonding member 130 adjacent to the edge of the base substrate 110. The region where the bonding member 130 is located and the region the extension wires 120 are located overlap, and this arrangement can further reduce the size of the non-display region 102 of the base substrate 110, thereby realizing a narrow bezel.

### Embodiment 2

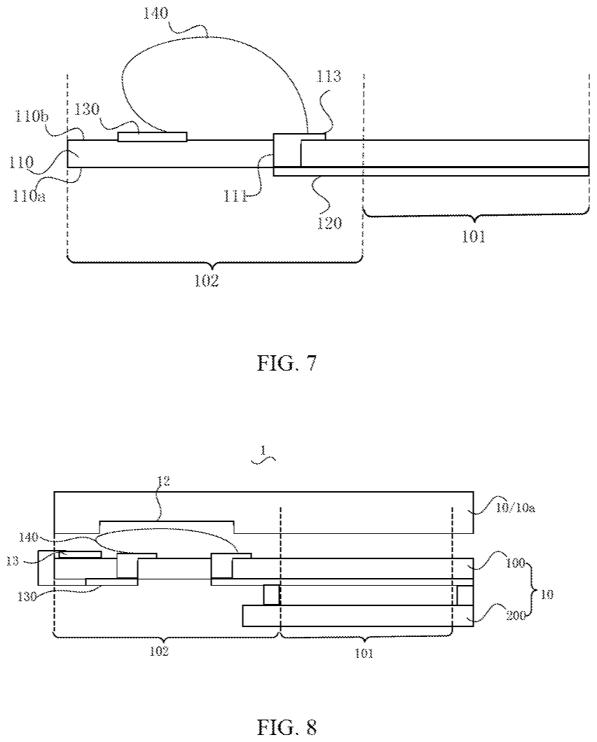

As shown in FIG. 7, as a second embodiment of the present application, a schematic diagram of an array substrate 100 is disclosed. The array substrate 100 includes a base substrate 110, a plurality of extension wires 120, a bonding member 130 and a flexible circuit board 140. The plurality of extension wires 120 are disposed on the front side 110a of the base substrate 110 and located in the non-display region 102. The bonding member 130 includes a plurality of bonding pins 130a, and the plurality of bonding pins 130a are arranged in the non-display region 102. The bonding pins 130a are disposed on the back side 110 b of the base substrate 110. The base substrate 110 is defined with a plurality of first through holes 111, the first through holes 111 are arranged at one end of the extension wires 120, and a first conductive layer 113 is arranged in the first through hole 111. The flexible circuit board 140 is disposed on the back side 110b of the base substrate 110. The extension wires 120 are electrically connected to one end of the flexible circuit board 140 through the first conductive layers 113. The other end of the flexible circuit board 140 is connected to the bonding pins 130a. In this solution, the bonding member 130 is also formed on the back side 110b, so only one set of through holes needs to be created, correspondingly connecting the extension wires 120 on the front side 110a with the flexible circuit board 140 on the back side 110b. The bonding member 130 is disposed on the back side 110b of the display panel, which further saves the space required for binding with the external driving circuit, and can form a display panel that does not require a bezel, such as a floating screen.

To further save space, the projections of the region where the bonding member 130 is located and the region where the extension wires 120 is located onto the base substrate 110 may partially overlap. The binding is arranged on the back side 110b, but is still arranged in the non-display region 102, that is, the through holes are defined at the edge of the base substrate 110. The bonding member 130 is arranged near the display region 101, and on the back side 110b the through holes and the bonding member 130 are connected together through the flexible circuit board 140. This solution can further reduce the width of the non-display region 102 on the base substrate 110, thereby realizing narrow-bezel display.

Of course, the projection of the region of the bonding member 130 on the base substrate 10 may also be arranged to overlap the projection of the region where the through hole is located on the base substrate 110. Specifically, after the extension wires 120 are converged to a certain extent, the plurality of extension wires 120 and the plurality of bonding pins 130a in the bonding member 130 are arranged at intervals. That is, the plurality of through holes and the plurality of bonding pins 130a are also arranged at intervals. One end of the flexible circuit board 140 is bonded with the conductive layer in the through hole, and the other end of the flexible circuit board 140 is bonded with the plurality of bonding pins 130a. Due to the spaced arrangement, the two bindings of the flexible circuit board 140 will not hinder each other, and this solution can also make the non-display region 102 of the base substrate 110 narrower.

### Embodiment 3

As shown in FIG. 8, as a third embodiment of the present application, a schematic diagram of a display device is disclosed. The display device 1 includes a display panel 10 and a backlight module 11. The display panel 10 includes the counter substrate 200 and the above-mentioned array substrate 100. The backlight module 11 includes a back plate 10a. The back plate 10a is disposed on the side of the array substrate 100 away from the counter substrate 200. The back plate 10 a is provided with a groove 12 corresponding to the flexible circuit board 140, and the flexible circuit board 140 is accommodated in the groove 12. The contents of the above embodiments of the present application can be widely used in various display panels, such as TN (Twisted Nematic) display panels, IPS (In-Plane Switching) display panels, VA (Vertical Alignment) display panels, and MVA (Multi-Domain Vertical Alignment) display panels panel, and can also be applied to COA (Color on Array) type display panels. Other types of display panels, such as OLED (Organic Light-Emitting Diode) display panels, may also be applicable to the above solutions.

It should be noted that the array substrate described in this embodiment and the different array substrates described in the above-mentioned embodiments are all applicable to this embodiment. The display device 1 further includes a driving circuit board 13, and the driving circuit board 13 is bonded on the bonding member 130 through a chip-on-chip film.

Since the flexible circuit board on the back needs to be bent, a certain accommodation space is required on the side of the array substrate adjacent to the back plate. A design such as an avoidance portion similar to a groove or a buffer portion can be correspondingly provided at the backlight module, for example, on a lamp bar or a back plate. Since the region corresponding to the fan-out traces of the base substrate is a non-display region, and the polarizer may not cover this region (the thickness of the polarizer is about 0.2-0.3 mm), there is a certain gap in this region to place the flexible circuit board. Considering the through hole in the back or the extension wires on the back, the wires will come into contact with the back plate, etc., and the metal traces on the back are exposed and are easily scratched, so in this embodiment, a layer of insulating UV glue can also be sprayed, which can also have a certain protective effect on through-holes or wiring in the case of preventing leakage or short circuit. Similarly, a layer of insulating and light-shielding material can also be sprayed on the back, and the design of insulation and light-shielding corresponding to the non-display region is contemplated.

It should be noted that the inventive concept of the present application can be formed into many embodiments, but the length of the application document is limited and so these embodiments cannot be enumerated one by one. The technical features can be arbitrarily combined to form a new embodiment, and the original technical effect may be enhanced after the various embodiments or technical features are combined. The foregoing description is merely a further detailed description of the present application made with reference to some specific illustrative embodiments, and the specific implementations of the present application will not be construed to be limited to these illustrative embodiments. For those having ordinary skill in the technical field to which this application pertains, numerous simple deductions or substitutions may be made without departing from the concept of this application, which shall all be regarded as falling in the scope of protection of this application.

What is claimed is:

1. An array substrate, comprising a display region and a non-display region, wherein the array substrate comprises:
a base substrate;
a plurality of extension wires, disposed on a front side of the base substrate and located in the non-display region of the array substrate;
a bonding member, comprising a plurality of bonding pins disposed in the non-display region of the array substrate; and
a flexible circuit board, disposed on a back side of the base substrate;
wherein a plurality of first through holes is defined in the base substrate; a first conductive layer is disposed in each of the plurality of first through holes;
wherein one end of each of the plurality of extension wires adjacent to the respective first through hole is electrically connected to one end of the flexible circuit board through the first conductive layer disposed in the respective first through hole, and wherein the other end of the each of the plurality of extension wires is connected to a respective data line or scan line disposed on the array substrate; and
wherein the other end of the flexible circuit board is connected to the plurality of bonding pins of the bonding member.

2. The array substrate as recited in claim 1, wherein the plurality of bonding pins are arranged on the front side of the base substrate;
wherein a plurality of second through holes are further defined in the base substrate, and a second conductive layer is disposed in each of the plurality of second through holes, wherein the other end of the flexible circuit board is electrically connected to the bonding member through the respective second conductive layers disposed in the plurality of second through holes.

3. The array substrate as recited in claim 2, wherein the bonding member comprises a first bonding portion and a second bonding portion, wherein the first bonding portion comprises a plurality of first bonding pins, and the second bonding portion comprises a plurality of second bonding pins,
wherein with one of the plurality extension wires in a middle as a center line, along a wire length direction of the plurality of extension wires, the plurality of extension wires gradually converge toward the center line, and wherein a distance between every two adjacent extension wires adjacent to an end of the plurality of first through holes is smaller than a distance between every two adjacent extension wires adjacent to an end of the display region;
wherein the first bonding portion and the second bonding portion are respectively arranged on both sides of the plurality of extension wires;
wherein the flexible circuit board comprises a first flexible circuit board and a second flexible circuit board; the plurality of extension wires comprises a plurality of first extension wires and a plurality of second extension wires; wherein the plurality of first extension wires are respectively connected to the first bonding pins through the first flexible circuit board, and the second extension wires are respectively connected to the second bonding pins through the second flexible circuit board.

4. The array substrate as recited in claim 1, wherein the plurality of bonding pins are arranged on the back side of the base substrate.

5. The array substrate as recited in claim 4, wherein an orthographic projection of a region of the plurality of the plurality of bonding pins on the base substrate overlaps an orthographic projection of a region of the plurality of extension wires on the base substrate.

6. The array substrate as recited in claim 1, wherein a distance between the bonding member and the plurality of extension wires is less than a length of the flexible circuit board.

7. The array substrate as recited in claim 1, wherein a plurality of signal traces are disposed in the flexible circuit board and have equal wire resistances.

8. The array substrate as recited in claim 1, wherein in a wire width direction of the plurality of extension wires, every two adjacent first through holes are staggered.

9. The array substrate as recited in claim 1, wherein no fan-out traces are disposed on the front side of the base substrate, the flexible circuit board is bendably disposed on the back side of the base substrate, and wherein each trace disposed on the flexible circuit board has an equal resistance.

10. The array substrate as recited in claim 9, wherein a distance between the bonding member and the plurality of extension wires is less than a length of the flexible circuit board.

11. The array substrate as recited in claim 9, wherein in a wire width direction of the plurality of extension wires, every two adjacent first through holes are staggered.

12. The array substrate as recited in claim 1, wherein widths of both ends of the flexible circuit board match a width of the region where the plurality of extension wires are located and a width of a region where the bonding member is located, respectively; and wherein the front side of the flexible circuit board has a shape of an isosceles trapezoid.

13. An array substrate, comprising a display region and a non-display region, wherein the array substrate comprises:
a base substrate;
a plurality of extension wires, disposed on a front side of the base substrate and located in the non-display region of the array substrate;
a bonding member, comprising a plurality of bonding pins disposed in the non-display region of the array substrate; and
a flexible circuit board, disposed on a back side of the base substrate;
wherein a plurality of first through holes is defined in the base substrate; a first conductive layer is disposed in each of the plurality of first through holes; wherein one end of each of the plurality of extension wires adjacent to the respective first through hole is electrically connected to one end of the flexible circuit board through the first conductive layer disposed in the respective first through hole, and wherein the other end of the each of the plurality of extension wires is connected to a respective data line or scan line disposed on the array substrate; and wherein the other end of the flexible circuit board is connected to the plurality of bonding pins of the bonding member;
wherein the plurality of bonding pins are arranged on the front side of the base substrate;
wherein a plurality of second through holes are further defined in the base substrate, and a second conductive layer is disposed in each of the plurality of second through holes, wherein the other end of the flexible circuit board is electrically connected to the bonding member through the respective second conductive layers disposed in the plurality of second through holes;
wherein the bonding member comprises a first bonding portion and a second bonding portion, wherein the first bonding portion comprises a plurality of first bonding pins, and the second bonding portion comprises a plurality of second bonding pins;
wherein with one of the plurality extension wires in a middle as a center line, along a wire length direction of the plurality of extension wires, the plurality of extension wires gradually converge toward the center line, and wherein a distance between every two adjacent extension wires adjacent to an end of the plurality of first through holes is smaller than a distance between every two adjacent extension wires adjacent to an end of the display region;
wherein the first bonding portion and the second bonding portion are respectively arranged on both sides of the plurality of extension wires;
wherein the flexible circuit board comprises a first flexible circuit board and a second flexible circuit board; the plurality of extension wires comprises a plurality of first extension wires and a plurality of second extension wires; wherein the plurality of first extension wires are respectively connected to the first bonding pins through the first flexible circuit board, and the second extension wires are respectively connected to the second bonding pins through the second flexible circuit board;
wherein a difference in resistances of the plurality of extension wires caused by convergence of the plurality of extension wires is balanced by a design of resistance of each trace on the flexible circuit board.

14. A display device, comprising a display panel and a backlight module, wherein the display panel comprises a counter substrate and an array substrate, wherein the counter substrate and the array substrate are aligned and bonded together to form a cell;
wherein the array substrate comprises:
a base substrate;
a plurality of extension wires, disposed on a front side of the base substrate and located in the non-display region of the array substrate;
a bonding member, comprising a plurality of bonding pins disposed in the non-display region of the array substrate; and
a flexible circuit board, disposed on a back side of the base substrate;
wherein a plurality of first through holes is defined in the base substrate; a first conductive layer is disposed in each of the plurality of first through holes;
wherein one end of each of the plurality of extension wires adjacent to the respective first through hole is electrically connected to one end of the flexible circuit board through the first conductive layer disposed in the respective first through hole, and wherein the other end of the each of the plurality of extension wires is connected to a respective data line or scan line disposed on the array substrate; and
wherein the other end of the flexible circuit board is connected to the plurality of bonding pins of the bonding member;
wherein the backlight module comprises a back plate, and a groove is defined in the back plate and corresponding to the flexible circuit board, and wherein the flexible circuit board is accommodated in the groove.

15. The array substrate as recited in claim 14, wherein the plurality of bonding pins are arranged on the front side of the base substrate;
wherein a plurality of second through holes are further defined in the base substrate, and a second conductive layer is disposed in each of the plurality of second through holes, wherein the other end of the flexible circuit board is electrically connected to the bonding member through the respective second conductive layers disposed in the plurality of second through holes.

16. The array substrate as recited in claim 15, wherein the bonding member comprises a first bonding portion and a second bonding portion, wherein the first bonding portion comprises a plurality of first bonding pins, and the second bonding portion comprises a plurality of second bonding pins,
wherein with one of the plurality extension wires in a middle as a center line, along a wire length direction of the plurality of extension wires, the plurality of extension wires gradually converge toward the center line, and wherein a distance between every two adjacent extension wires adjacent to an end of the plurality of first through holes is smaller than a distance between every two adjacent extension wires adjacent to an end of the display region;
wherein the first bonding portion and the second bonding portion are respectively arranged on both sides of the plurality of extension wires;
wherein the flexible circuit board comprises a first flexible circuit board and a second flexible circuit board; the plurality of extension wires comprises a plurality of first extension wires and a plurality of second extension wires; wherein the plurality of first extension wires are respectively connected to the first bonding pins through the first flexible circuit board, and the second extension wires are respectively connected to the second bonding pins through the second flexible circuit board.

17. The array substrate as recited in claim 14, wherein the plurality of bonding pins are arranged on the back side of the base substrate.

18. The array substrate as recited in claim 17, wherein an orthographic projection of a region of the plurality of the plurality of bonding pins on the base substrate overlaps an orthographic projection of a region of the plurality of extension wires on the base substrate.

19. The array substrate as recited in claim 14, wherein no fan-out traces are disposed on the front side of the base substrate, the flexible circuit board is bendably disposed on the back side of the base substrate, and wherein each trace disposed on the flexible circuit board has an equal resistance; wherein the plurality of bonding pins are arranged on the front side of the base substrate; wherein a plurality of second through holes are further defined in the base substrate, and a second conductive layer is disposed in each of the plurality of second through holes, wherein the other end of the flexible circuit board is electrically connected to the plurality of bonding pins through the respective second conductive layers disposed in the plurality of second through holes.

20. The display device as recited in claim 14, further comprising a driving circuit board bonded with the plurality of bonding pins.
